(19) United States
(12) Patent Application Publication
(10) Pub. No.: US 2024/0186289 A1
(43) Pub. Date: Jun. 6, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Hanmin Lee, Suwon-si (KR); Unbyoung Kang, Suwon-si (KR); Seongyo Kim, Suwon-si (KR); Sangsick Park, Suwon-si (KR)

(73) Assignee: SAMSUNG ELECTRONICS CO., LTD., Suwon-si (KR)

(21) Appl. No.: 18/226,990

(22) Filed: Jul. 27, 2023

(30) Foreign Application Priority Data
Dec. 2, 2022 (KR) 10-2022-0166320

(51) Int. Cl. H01L 25/065; H01L 21/461; H01L 21/56; H01L 23/00; H01L 23/31; H01L 25/00; H10B 80/00

(52) U.S. Cl. CPC H01L 25/0657; H01L 21/461; H01L 21/563; H01L 23/3114; H01L 24/16; H01L 24/32; H01L 25/50; H10B 80/00; H01L 2224/16145; H01L 2224/32145

(57) ABSTRACT

A method of manufacturing a semiconductor package comprises stacking, via an adhesive member, a plurality of memory dies to form a memory die stack on a buffer die; forming a first molding member on the buffer die to cover the memory die stack; polishing an upper surface of the first molding member to expose an upper surface of an uppermost memory die in the memory die stack, the uppermost memory die positioned in an uppermost layer in the memory die stack; removing edge portions of the uppermost memory die together with at least a portion of the first molding member and at least a portion of the adhesive member to form a stepped portion; and forming a second molding member on the first molding member to cover the stepped portion of the uppermost memory die.

### PRIORITY STATEMENT

This application claims priority under 35 U.S.C. § 119 to Korean Patent Application No. 10-2022-0166320, filed on Dec. 2, 2022 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a plurality of stacked chips and a method of manufacturing the same.

### 2. Description of the Related Art

In a bonding process of stacking a plurality of semiconductor chips, a non-conductive film (NCF) may fill up spaces between the stacked semiconductor chips. A molding member may cover the semiconductor chips stacked on one another. The non-conductive film may overflow from between the semiconductor chips, and the non-conductive film may be exposed from the molding member in a process in which the molding member covers the semiconductor chips. Since coefficients of thermal expansion of the molding member and the exposed non-conductive film are different from each other, a warpage phenomenon of semiconductor chips may disadvantageously occur. As a result of this warpage phenomenon, contact failure may occur between semiconductor chips.

### SUMMARY

Example embodiments provide a semiconductor package having a structure configured to preventing exposure of a non-conductive film from a molding member that covers stacked semiconductor chips.

Example embodiments provide a method of manufacturing the semiconductor package.

According to one or more embodiments, a method of manufacturing a semiconductor package, comprises stacking, via an adhesive member, a plurality of memory dies to form a memory die stack on a buffer die: forming a first molding member on the buffer die to cover the memory die stack: polishing an upper surface of the first molding member to expose an upper surface of an uppermost memory die in the memory die stack, the uppermost memory die positioned in an uppermost layer in the memory die stack: removing edge portions of the uppermost memory die together with at least a portion of the first molding member and at least a portion of the adhesive member to form a stepped portion: and forming a second molding member on the first molding member to cover the stepped portion of the uppermost memory die.

According to one or more embodiments, a semiconductor package, comprises: a buffer die: a plurality of memory dies sequentially stacked to form a memory die stack on the buffer die, the memory die stack including a uppermost memory die that has a stepped portion, the stepped portion extending along edge portions of an upper surface of the uppermost memory die: an adhesive member filling up between the plurality of memory dies in the memory die stack, the adhesive member overflowing from between the plurality of memory dies under the stepped portion: a first molding member covering the memory die stack and the adhesive member on the buffer die: and a second molding member covering the stepped portion of the uppermost memory die in the memory die stack on the first molding member and the adhesive member.

According to one or more embodiments, a method of manufacturing a semiconductor package, comprises: stacking a plurality of memory dies to form a memory die stack on a buffer die via an adhesive member; forming a first molding member on the buffer die to cover the memory die stack and a portion of the adhesive member that overflows from between the memory dies: polishing an upper surface of the first molding member to expose an upper surface of an uppermost memory die in the memory die stack, the uppermost memory die positioned in an uppermost layer in the memory die stack: removing edge portions of the uppermost memory die in the memory die stack together with at least a portion of the first molding member and at the portion of the adhesive member to form a stepped portion; forming a second molding member on the first molding member to cover the stepped portion of the uppermost memory die in the memory die stack: and polishing an upper surface of the second molding member to expose the upper surface of the uppermost memory die in the memory die stack.

Thus, in a process of stacking the memory dies to form a memory die stack on the buffer die through the adhesive member, the adhesive member may overflow from between the memory dies in the memory die stack. The edge portions of the uppermost memory die may be removed along with the overflowed adhesive member to form the stepped portion. Since the overflowed adhesive member is removed in a process of forming the stepped portion, the adhesive member may not remain on the stepped portion. Since the uppermost memory die is once again covered through the second molding member, the adhesive member may not be exposed from the second molding member.

Since the adhesive member is not exposed from the second molding member, a warpage phenomenon of the semiconductor chips that is caused by a difference in coefficients of thermal expansion between the adhesive member and the second molding member may be advantageously prevented.

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a plan view illustrating a semiconductor package in accordance with example embodiments.

FIG. 2 is cross-sectional views taken along the line A-A′ in FIG. 1 in accordance with example embodiments.

FIG. 3 illustrates providing a semiconductor wafer W having a plurality of first semiconductor chips on a carrier substrate C1 as part of a method of manufacturing a semiconductor package in accordance with example embodiments.

FIG. 4 illustrates attaching semiconductor chips to a semiconductor wafer W as part of a method of manufacturing a semiconductor package in accordance with example embodiments.

FIG. 5 illustrates attaching semiconductor chips to a semiconductor wafer W as part of a method of manufacturing a semiconductor package in accordance with example embodiments.

FIG. 6 illustrates forming a molding member on a semiconductor wafer W as part of a method of manufacturing a semiconductor package in accordance with example embodiments.

FIG. 7 illustrates forming a molding member on a semiconductor wafer W as part of a method of manufacturing a semiconductor package in accordance with example embodiments.

FIG. 8 illustrates removing edge portion from a semiconductor chip to form a trench as part of a method of manufacturing a semiconductor package in accordance with example embodiments.

FIG. 9 illustrates removing edge portion from a semiconductor chip to form a trench as part of a method of manufacturing a semiconductor package in accordance with example embodiments.

FIG. 10 illustrates forming a second molding member on the semiconductor wafer W to cover a semiconductor chip, adhesive member, and molding member as part of a method of manufacturing a semiconductor package in accordance with example embodiments.

FIG. 11 illustrates forming a second molding member on the semiconductor wafer W to cover a semiconductor chip, adhesive member, and molding member as part of a method of manufacturing a semiconductor package in accordance with example embodiments.

FIG. 12 illustrates forming a second molding member on the semiconductor wafer W to cover a semiconductor chip, adhesive member, and molding member as part of a method of manufacturing a semiconductor package in accordance with example embodiments.

FIG. 13 illustrates cutting molding members along a scribe lane region to form a semiconductor package.

### DETAILED DESCRIPTION OF EXAMPLE EMBODIMENTS

Hereinafter, example embodiments will be explained in detail with reference to the accompanying drawings.

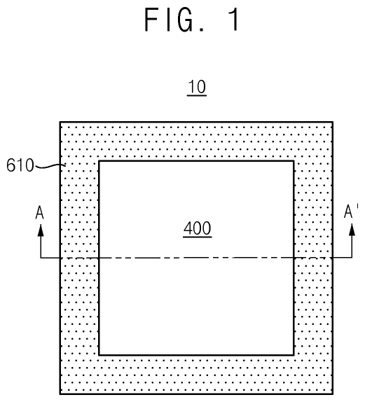

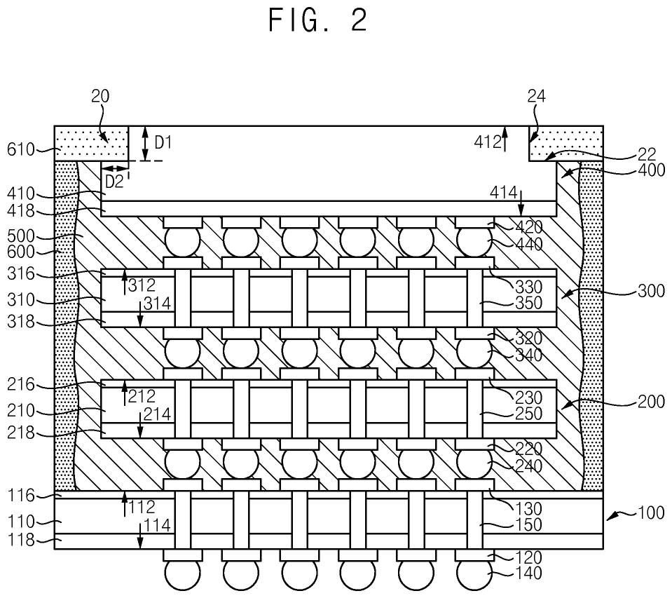

FIG. 1 is a plan view illustrating a semiconductor package in accordance with example embodiments. FIG. 2 is cross-sectional views taken along the line A-A′ in FIG. 1.

Referring to FIGS. 1 and 2, a semiconductor package 10 may include a plurality of stacked semiconductor chips. The semiconductor package 10 may include stacked first to fourth semiconductor chips 100, 200, 300, and 400, respectively. The semiconductor package 10 may include an adhesive member 500 that fills up between the stacked first to fourth semiconductor chips 100, 200, 300, and 400, respectively, and attaches the stacked first to fourth semiconductor chips to each other. For example, the adhesive 500 may be deposited in the open spaces between the stacked semiconductor chips. The semiconductor package 10 may include a first molding member 600 covering the second to fourth semiconductor chips (e.g., memory dies) 200, 300, and 400, respectively, on the first semiconductor chip (buffer die) 100, and a second molding member 610 covering the first molding member 600.

The plurality of semiconductor chips 100, 200, 300, and 400 may be vertically stacked. The first to fourth semiconductor chips 100, 200, 300, and 400 may be substantially the same as or similar to each other. Thus, the same or similar elements are denoted by the same or similar reference numerals, and repeated description of the same elements may be omitted. As understood by one of ordinary skill in the art, one or more of the semiconductor chips may be different from one another.

In one or more embodiments, a semiconductor package as a multi-chip package is illustrated as including four stacked semiconductor chips 100, 200, 300, and 400. However, as understood by one of ordinary skill in the art, the embodiments are not limited to these configurations, and for example, the semiconductor package may include 8, 12, or 16 stacked semiconductor chips.

Each of the first to fourth semiconductor chips 100, 200, 300, and 400, respectively, may include an integrated circuit chip that is completed by performing semiconductor manufacturing processes. Each of the semiconductor chips may include, for example, a memory chip or a logic chip. The semiconductor package 10 may include a memory device. The memory device may include a high bandwidth memory (HBM) device. The memory device may include any memory device structure known to one of ordinary skill in the art.

Hereinafter, the first semiconductor chip 100 will be described.

According to one or more embodiments, as illustrated in FIG. 2, the first semiconductor chip 100 may include a first substrate 110 having a first upper surface 112 and a first lower surface 114 opposite to each other, one or more first connecting pads 120 provided on the first lower surface 114, one or more first bonding pads 130 provided on the first upper surface 112, and one or more first conductive bump 140 provided on the first connecting pad 120. The first semiconductor chip 100 may further include a first through electrode 150 penetrating the first substrate 110, and a first protective layer 116 provided on the first upper surface 112. As illustrated in FIG. 2, a first bonding pad 130 may be provided for each first connecting pad 120 and first conductive bump 140.

The first upper surface 112 of the first substrate 110 may be referred to as an inactive surface, and the first lower surface 114 may be referred to as an active surface. Circuit patterns may be provided on the first lower surface 114 of the first substrate 110. The first lower surface 114 may be referred to as a front side surface on which the circuit patterns are formed, and the first upper surface 112 may be referred to as a back side surface.

For example, the first substrate 110 may include semiconductor material such as silicon, germanium, or silicon-germanium. The first substrate 110 may include a III-V compound such as gallium phosphide (GaP), gallium arsenide (GaAs), or gallium antimonide (GaSb). The first substrate 110 may include a Silicon-On-Insulator (SOI) substrate or a Germanium-On-Insulator (GOI) substrate.

The circuit patterns may include transistors, diodes, or any other semiconductor structure known to one of ordinary skill in the art. The circuit patterns may constitute circuit elements. Thus, the first semiconductor chip 100 may be referred to as a semiconductor device in which a plurality of the circuit elements are formed.

In example embodiments, a first activation layer 118 may be provided on the first lower surface 114 of the first substrate 110. The first activation layer 118 may include an insulating layer and a plurality of redistribution wires provided in the insulating layer. The redistribution wires may be connected to one side of the first through electrode 150. The first connecting pad 120 may be connected to the redistribution wires that are electrically connected to the first through electrode 150. The insulating layer may include silicon oxide, carbon-doped silicon oxide, silicon carbonitride (SiCN), or any other suitable material known to one of ordinary skill in the art.

The first conductive bump 140 may be provided on the first connecting pad 120. The first conductive bump 140 may provide an electrical movement path configured to electrically connecting the first semiconductor chip 100 to other semiconductor devices. The first conductive bump 140 may dispose the first semiconductor chip 100 on the other semiconductor device. For example, the first conductive bump 140 may include micro bumps (uBumps).

The first protective layer 116 may be provided on the first upper surface 112 of the first substrate 110. The first protective layer 116 may include an insulating material to protect the first substrate 110 from outside. The first protective layer 116 may include an oxide film or a nitride film. The first protective layer 116 may include a double layer of an oxide film and a nitride film. The first protective layer 116 may include an oxide film, a silicon oxide film (SiO₂) formed by a high-density plasma chemical vapor deposition (HDP-CVD) process.

The first bonding pad 130 may be provided on the first protective layer 116, and may be electrically connected to the first through electrode 150. The first bonding pad 130 may be electrically connected to the first through electrode 150 at other side that is opposite to the one side of the first through electrode 150.

The first through electrode 150 may penetrate the first substrate 110 in a vertical direction. The one side of the first through electrode 150 may be electrically connected to the redistribution wires. The other side of the first through electrode 150 may be exposed to the first upper surface 112 of the first substrate 110. The first through electrode 150 may be electrically connected to the first bonding pad 130 through the exposed other side.

Each of the first connecting pads 120, the first bonding pads 130, and the first through electrodes 150 may include a metal material. For example, the metal material may include copper (Cu), aluminum (Al), tungsten (W), nickel (Ni), molybdenum (Mo), gold (Au), silver (Ag), chromium (Cr), tin (Sn) and titanium (Ti). However, as understood by one of ordinary skill in the art, the embodiments are not limited to these materials or configurations, and the metal material may include a material configured to be bonded by interdiffusion of metals by a high-temperature annealing process.

In example embodiments, the second semiconductor chip 200 may include a second substrate 210, one or more second bonding pads 230 provided on a second upper surface 212 of the second substrate 210, one or more second connecting pads 220 provided on a second lower surface 214 of the second substrate 210, and one or more second conductive bumps 240 provided on the second connecting pad 220. The second semiconductor chip 200 may further include one or more second through electrodes 250 penetrating the second substrate 210 in the vertical direction, and a second protective layer 216 provided on the second upper surface 212. A second activation layer 218 may be provided on the second lower surface 214 of the second substrate 210. As illustrated in FIG. 2, a first bonding pad 130 may be provided for each first connecting pad 120 and first conductive bump 140.

The second substrate 210 may be disposed on the first substrate 110 such that the second lower surface 214 of the second substrate 210 faces the first upper surface 112 of the first substrate 110. Each second conductive bump 240 of the second semiconductor chip 200 may be directly bonded to a respective first bonding pad 130 of the first semiconductor chip 100. The second semiconductor chip 200 may be disposed on the first semiconductor chip 100 by a flip chip bonding method. Each second connecting pad 220 of the second semiconductor chip 200 may be electrically connected to the respective first bonding pad 130 of the first semiconductor chip 100 through a respective second conductive bump 240.

In example embodiments, the third semiconductor chip 300 may include a third substrate 310, one or more third bonding pad 330 provided on a third upper surface 312 of the third substrate 310, one or more third connecting pads 320 provided on a third lower surface 314 of the third substrate 310, and one or more third conductive bumps 340 provided on the third connecting pad 320. The third semiconductor chip 300 may further include one or more third through electrodes 350 penetrating the third substrate 310 in the vertical direction, and a third protective layer 316 provided on the third upper surface 312. A third activation layer 318 may be provided on the third lower surface 314 of the third substrate 310. The third semiconductor chip 300 may be disposed on the second semiconductor chip 200 by the flip chip bonding method.

The fourth semiconductor chip (uppermost memory die) 400 may include a fourth substrate 410, and one or more fourth connecting pads 420 provided on a fourth lower surface 414 opposite to a fourth upper surface 412 of the fourth substrate 410. A fourth activation layer 418 may be provided on the fourth lower surface 414 of the fourth substrate 410. The fourth semiconductor chip 400 may include a fourth conductive bump 440 provided on the fourth connecting pad 420. The fourth semiconductor chip 400 may be disposed on the third semiconductor chip 300 by the flip chip bonding method.

In example embodiments, the fourth semiconductor chip 400 may include a stepped portion 20 extending along edge portions of an upper surface of the fourth semiconductor chip 400. The stepped portion 20 may be provided on the fourth upper surface 412 of the fourth substrate 410. At least a portion of the silicon substrate of the fourth substrate 410 may be removed to form the stepped portion 20.

The stepped portion 20 may have a horizontal portion (e.g., bottom portion) 22, and a vertical portion 24 (e.g., sidewall portion) extending from the horizontal portion 22 in the vertical direction. The horizontal portion 22 of the stepped portion 20 may extend from an outer surface of the fourth substrate 410, and the vertical portion 24 may extend from the fourth upper surface 412 of the fourth substrate 410. The horizontal portion 22 of the stepped portion 20 may be provided to be spaced apart from the fourth activation layer 418 in the vertical direction.

The horizontal portion 22 of the stepped portion 20 may be provided to be spaced apart from the fourth upper surface 412 of the fourth substrate 410 by a predetermined depth D1. For example, the predetermined depth D1 may be within a range of 10 μm to 100 μm.

The vertical portion 24 of the stepped portion 20 may be provided to be spaced apart from the outer surface of the fourth substrate 410 by a predetermined distance D2. For example, the predetermined distance D2 may be within a range of 10 μm to 50 μm.

The upper surface and a lower surface opposite to the upper surface of the fourth semiconductor chip 400 may have different areas due to the stepped portion 20. A ratio (A2/A1) of an area A1 of the upper surface and an area A2 of the lower surface of the fourth semiconductor chip 400 may be within a range of 1.01 to 1.1. Although FIG. 2 illustrates one step portion, as understood by one of ordinary skill in the art, the embodiments are not limited to this configuration. For example, the a plurality of step portions may be provided on the fourth upper surface 412 of the fourth substrate 410. In example embodiments, the adhesive member 500 may underfill up between the first to fourth semiconductor chips 100, 200, 300, and 400, respectively. A sufficient amount of adhesive member 500 may be applied such that the adhesive member 500 overflows from between the first to fourth semiconductor chips 100, 200, 300, and 400, respectively, on the first semiconductor chip 100.

The overflowed adhesive member 500 may cover outer surfaces of the second and third semiconductor chips 200 and 300, respectively. The overflowing adhesive member 500 may cover at least a portion of an outer surface of the fourth semiconductor chip 400. The overflowed adhesive member 500 might not be provided on the stepped portion 20 of the fourth semiconductor chip 400. An upper surface of the overflowed adhesive member 500 may be provided on the same plane as the horizontal portion 22 of the stepped portion 20.

In one or more examples, the adhesive member 500 may include a non-conductive film (NCF) material. The adhesive member 500 may include a die attach film (DAF), an epoxy molding compound (EMC), an epoxy resin, a UV resin, a polyurethane resin, A silicone resin and a silica filler.

In example embodiments, the first molding member 600 may cover outer surfaces of the second to fourth semiconductor chips 200, 300, and 400, respectively, on the first semiconductor chip 100. The first molding member 600 may cover at least a portion of the overflowing adhesive member 500 from the first to fourth semiconductor chips 100, 200, 300, and 400, respectively. The first molding member 600 might not be provided on the stepped portion 20 of the fourth semiconductor chip 400. An upper surface of the first molding member 600 may be provided on the same plane as the horizontal portion 22 of the stepped portion 20.

In example embodiments, the second molding member 610 may cover the second to fourth semiconductor chips 200, 300, and 400, respectively on the first semiconductor chip 100. The second molding member 610 may cover at least a portion of the overflowing adhesive member 500 from the first to fourth semiconductor chips 100, 200, 300, and 400, respectively. The second molding member 610 may cover the first molding member 600 and the adhesive member 500 on the first semiconductor chip 100.

The second molding member 610 may cover the stepped portion 20 of the fourth semiconductor chip 400, the first molding member 600, and the adhesive member 500. The second molding member 610 may cover the horizontal portion 22 and the vertical portion 24 of the stepped portion 20. An upper surface of the second molding member 610 may be provided on the same plane as the fourth upper surface 412 of the fourth substrate 410.

The first molding member 600 may include a first mold material. The second molding member 610 may include a second mold material different from the first mold material. In one or more examples, the first mold material of the first molding member 600 may be the same as the second mold material of the second molding member 610. For example, each of the first and second mold materials may include epoxy mold compound (EMC), UV resin, polyurethane resin, silicone resin, silica filler, or any other suitable material known to one of ordinary skill in the art.

Hereinafter, a method of manufacturing the semiconductor package in FIG. 1 will be described.

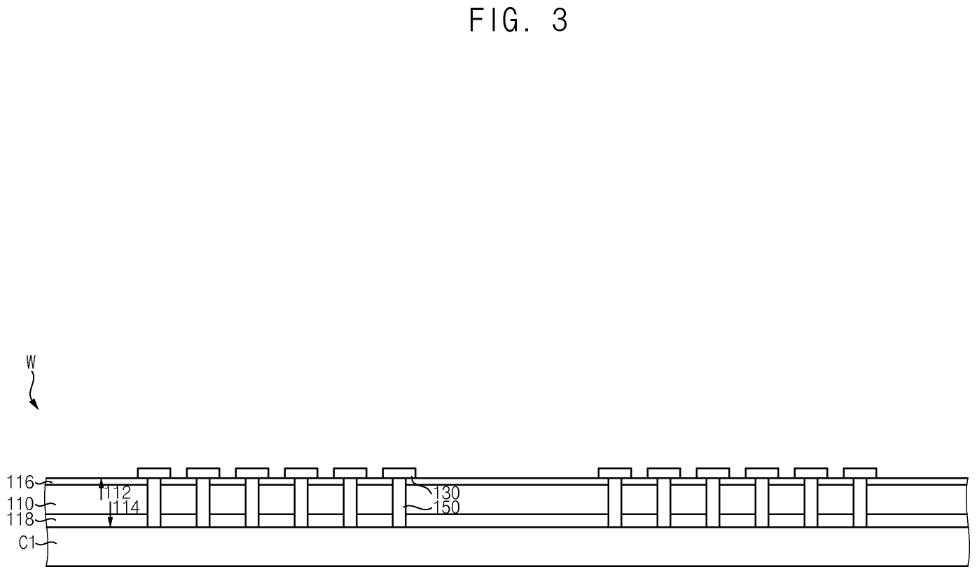

FIGS. 3 to 13 are views illustrating a method of manufacturing a semiconductor package in accordance with example embodiments.

Referring to FIG. 3, first, a semiconductor wafer W having a plurality of first semiconductor chips (e.g., dies) may be provided on a carrier substrate C1.

In example embodiments, the semiconductor wafer W may include a first substrate 110, one or more first through electrodes 150 partially penetrating the first substrate 110, and one or more first bonding pads 130 provided on a respective first through electrode 150.

For example, the first substrate 110 may include a semiconductor material such as silicon, germanium, or silicon-germanium. The first substrate 110 may include a III-V compound such as gallium phosphide (GaP), gallium arsenide (GaAs), or gallium antimonide (GaSb). The first substrate 110 may include a Silicon-On-Insulator (SOI) substrate or a Germanium-On-Insulator (GOI) substrate.

The first substrate 110 may have a first upper surface 112 and a first lower surface 114 opposite to each other. A first activation layer 118 may be provided on the first lower surface 114 of the first substrate 110. The first activation layer 118 may include an insulating layer, and a plurality of redistribution wires provided in the insulating layer. The redistribution wires may be connected to one side of the first through electrode 150. Circuit patterns may be formed in the first activation layer 118.

The first substrate 110 may include a die region where the circuit patterns and cells are formed, and a scribe lane region surrounding the die region. The first substrate 110 may be individualized by being cut along the scribe lane region that divides a plurality of the die regions of the semiconductor wafer W by a sawing process.

The circuit patterns may include transistors, capacitors, diodes, or any other circuit structure known to one of ordinary skill in the art. The circuit patterns may constitute circuit elements. Thus, the first semiconductor chip may be referred to as a semiconductor device in which a plurality of the circuit elements are formed. A front end of line (FEOL) process for manufacturing semiconductor devices may be performed to form the circuit patterns on the first lower surface 114 of the first substrate 110. A surface of the first substrate on which the FEOL process is performed may be referred to as a front side surface of the first substrate, and a surface opposite to the front side surface may be referred to as a back side surface.

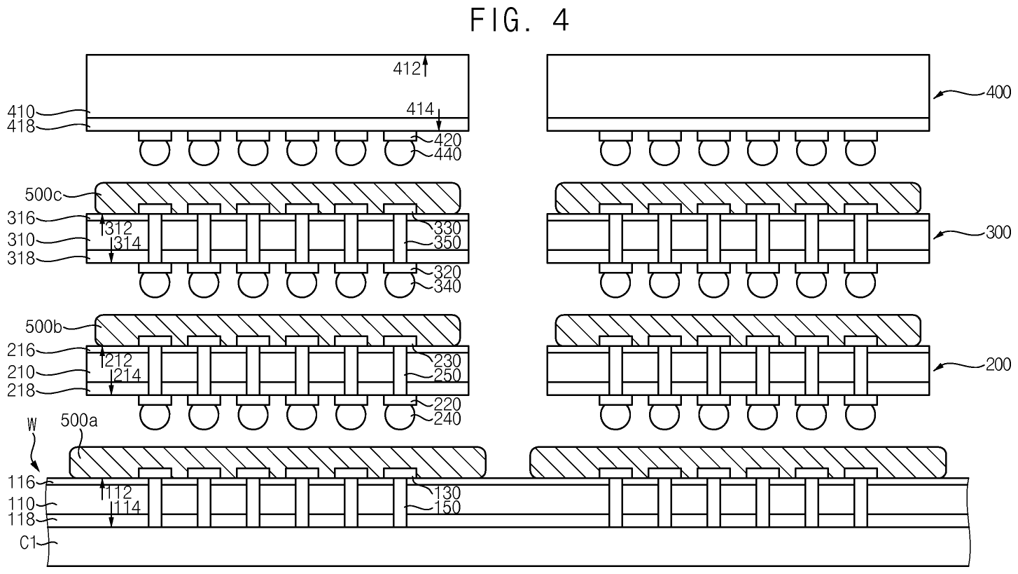

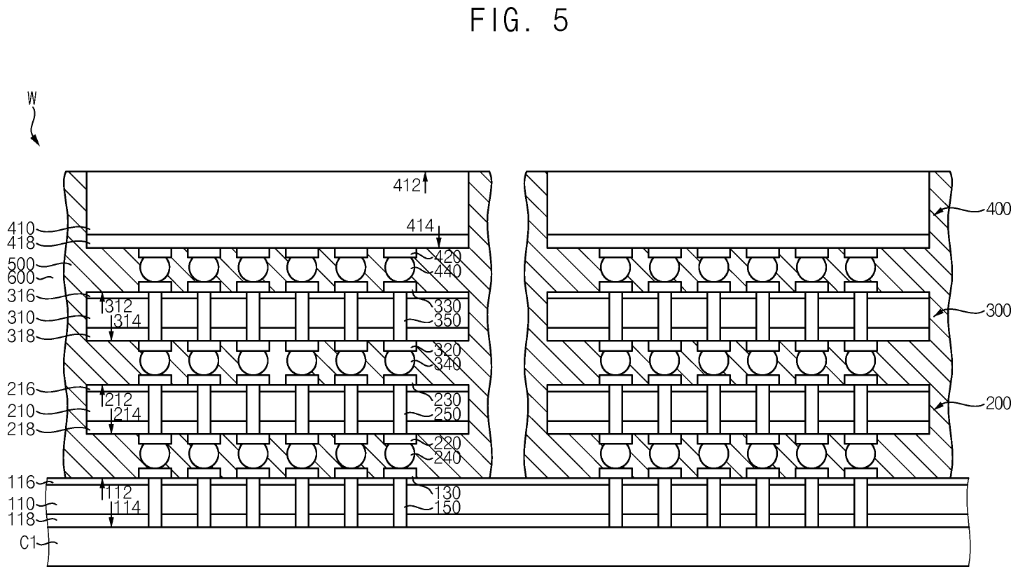

Referring to FIGS. 4 and 5, second semiconductor chips 200 may be attached on the semiconductor wafer W. The same process as the second semiconductor chip 200 may be performed to attach third semiconductor chips 300 on the second semiconductor chips 200. The fourth semiconductor chip 400 may be attached on the third semiconductor chip 300. The second to fourth semiconductor chips 200, 300, and 400, respectively, may be attached on the semiconductor wafer W by a flip chip bonding method. In one or more examples, the second to fourth semiconductor chips 200, 300, and 400 may be sequentially stacked on the first semiconductor chip. In one or more examples, the second to fourth semiconductor chips 200, 300, and 400 may be sequentially stacked to on each other starting with second semiconductor chip 200, and subsequently stacked on the first semiconductor chip.

In example embodiments, the second semiconductor chips 200 may be disposed on the semiconductor wafer W to correspond to the die regions. A second lower surface 214 of the second substrate 210 of the second semiconductor chip 200 may face the semiconductor wafer W.

A thermal compression process at a predetermined temperature may be performed to attach the second semiconductor chip 200 on the first upper surface 112 of the semiconductor wafer W. The second semiconductor chip 200 and the semiconductor wafer W may be bonded to each other by the thermal compression process. For example, each second conductive bump 240 of the second semiconductor chip 200 may be bonded to a respective first bonding pad 130 provided on the first upper surface 112 of the semiconductor wafer W, respectively. An adhesive material 500a may be formed between the semiconductor wafer W and the second semiconductor chip 200 in the thermal compression process. For example, the adhesive material 500a may include a non-conductive film (NCF) material.

After the adhesive is applied between the wafer W and the semiconductor chip 200, the third and fourth semiconductor chips 300 and 400 may be sequentially disposed on the second semiconductor chip 200. A front side surface of the third semiconductor chip 300 may be stacked to face a back side surface of the second semiconductor chip 200. A front surface of the fourth semiconductor chip 400 may be stacked to face a back side surface of the third semiconductor chip 300. An adhesive material 500b may be formed between the second and third semiconductor chips 200 and 300 in the thermal compression process.

In the thermal compression process, the third semiconductor chip 300 and the second semiconductor chip 200 may be bonded to each other by the flip chip bonding method. For example, each third conductive bump 340 of the third semiconductor chip 300 may be directly bonded to a respective second bonding pad 230 of the second semiconductor chip 200.

In the thermal compression process, the fourth semiconductor chip 400 and the third semiconductor chip 300 may be bonded to each other by the flip chip bonding method. For example, each fourth conductive bump 440 of the fourth semiconductor chip 400 may be directly bonded to a respective third bonding pad 330 of the third semiconductor chip 300. An adhesive material 500c may be formed between the third and fourth semiconductor chips 300 and 400 in the thermal compression process.

In one or more embodiments, the number of stacked semiconductor chips may be not limited thereto, and for example, 4, 8, and 12 semiconductor chips may be sequentially stacked on the fourth semiconductor chip 400.

The adhesive materials 500a, 500b, and 500c may be dispersed between the second to fourth semiconductor chips 200, 300, and 400, respectively, by the thermal compression process. The adhesive materials 500a, 500b, and 500c filling up between the semiconductor wafer W and the second to fourth semiconductor chips 200, 300, and 400, respectively, may overflow from between the semiconductor chips. The adhesive materials 500a, 500b, and 500c may be hardened to form the adhesive member 500. The overflowed adhesive member 500 may cover at least a portion of outer surfaces of the second to fourth semiconductor chips 200, 300, and 400, respectively. For example, the adhesive member 500 surrounds at least side surfaces of the second to fourth semiconductor chips 200, 300, and 400, respectively.

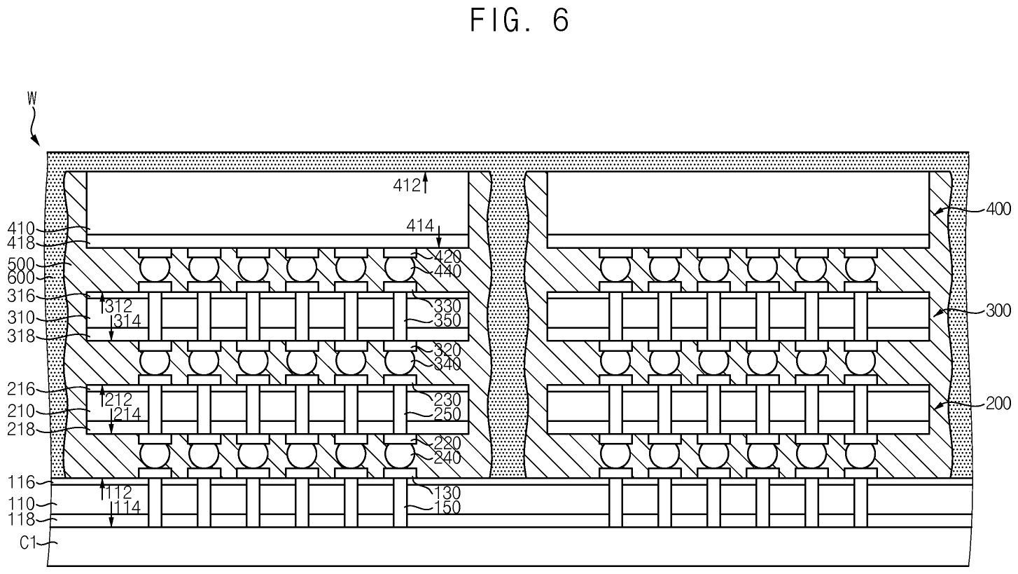

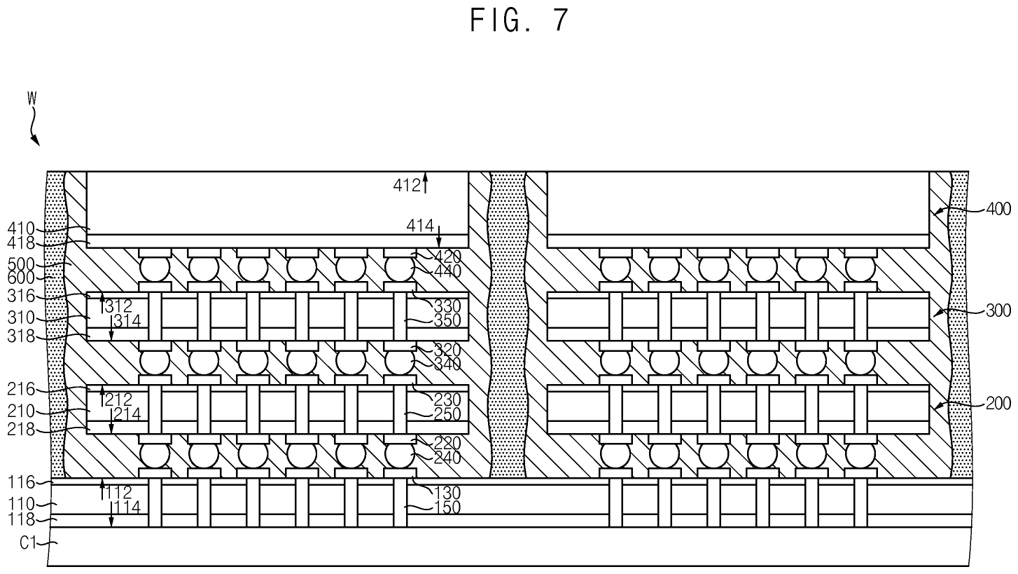

Referring to FIGS. 6 and 7, a first molding member 600 may be formed on a semiconductor wafer W to cover the second to fourth semiconductor chips 200, 300, and 400, respectively.

In example embodiments, the first molding member 600 may be formed on the semiconductor wafer W to fill up spaces between the second to fourth semiconductor chips 200, 300, and 400, respectively. The first molding member 600 may be formed to surround the second to fourth semiconductor chips 200, 300, and 400, respectively. The first molding member 600 may be formed to surround the overflowed adhesive member 500. For example, the adhesive member 500 surrounds at least side surfaces of the second to fourth semiconductor chips 200, 300, and 400, respectively, and the top surface of the fourth semiconductor chip 400.

The first molding member 600 may be formed by a dispensing process or a spin coating process. The first molding member 600 may include a first mold material. For example, the first mold material may include an epoxy mold compound (EMC), a UV resin, a polyurethane resin, a silicone resin, or a silica filler.

As illustrated in FIG. 7, an upper surface of the first molding member 600 may be polished by a substrate support system (WSS). The upper surface of the first molding member 600 may be removed until an upper surface of the fourth semiconductor chip 400 is exposed.

The upper surface of the first molding member 600 may be partially removed by a grinding process such as a chemical mechanical polishing (CMP) process. Thus, a thickness of the first molding member 600 may be reduced to a desired thickness. The upper surface of the fourth semiconductor chip 400 may be exposed from the upper surface of the first molding member 600. The adhesive member 500 formed on the upper surface of the fourth semiconductor chip 400 may be removed together with a portion of the first molding member 600.

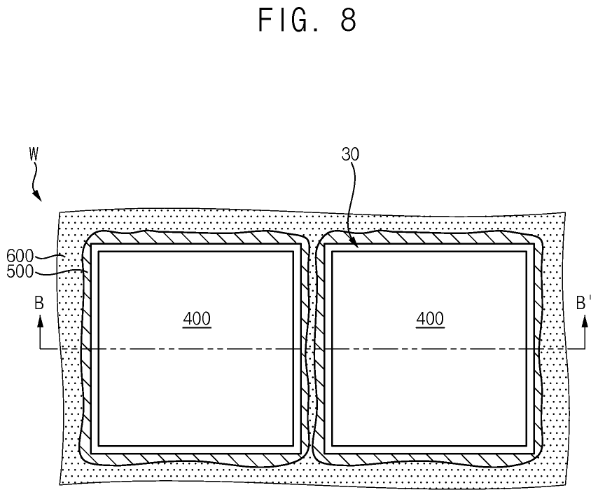

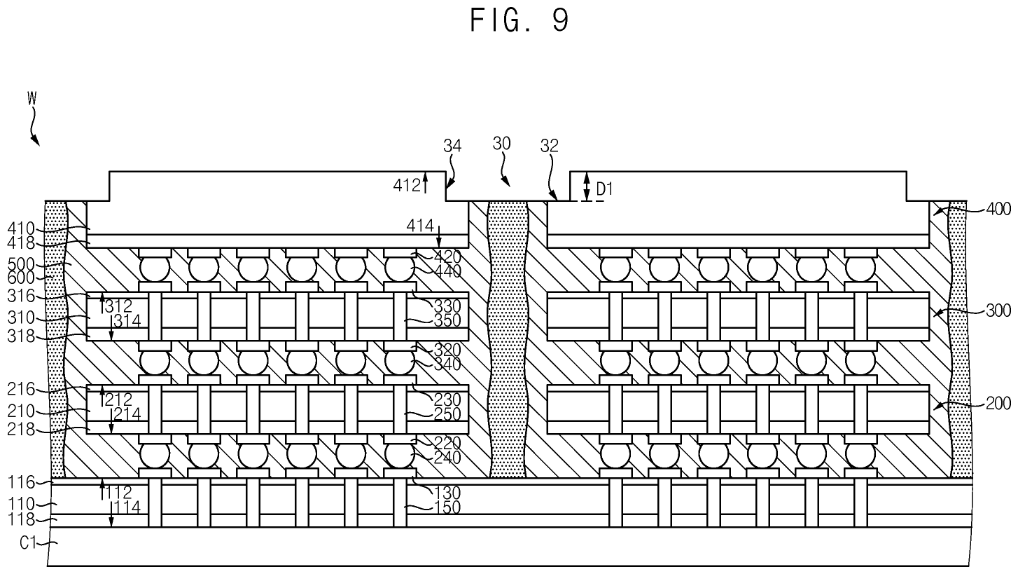

FIG. 8 is a plan view illustrating a semiconductor wafer in which a plurality of semiconductor chips are stacked in accordance with one or more embodiments. FIG. 9 is cross-sectional view taken along the line B-B′ in FIG. 8.

Referring to FIGS. 8 and 9, edge portions of the fourth semiconductor chip 400 may be removed to form a trench 30. The trench 30 may be formed by removing the edge portions of the fourth semiconductor chip 400 together with at least a portion of the first molding member 600 and the adhesive member 500.

The trench 30 may have a side wall 34, and a bottom surface 32 extending from the side wall 34 in a horizontal direction. The bottom surface 32 of the trench 30 may be formed to be spaced apart from a fourth activation layer 418 in the vertical direction. At least a portion of the first molding member 600 and at least a portion of the adhesive member 500 may constitute the bottom surface 32 of the trench 30. The trench 30 may be formed by a blade cutting process.

The bottom surface 32 of the trench 30 may have a predetermined depth D1 from a fourth upper surface 412 of the fourth substrate 410. For example, the predetermined depth D1 may be within a range of 10 μm to 100 μm.

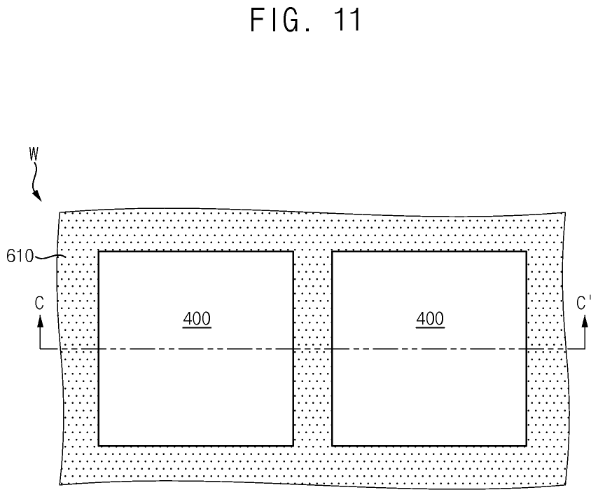

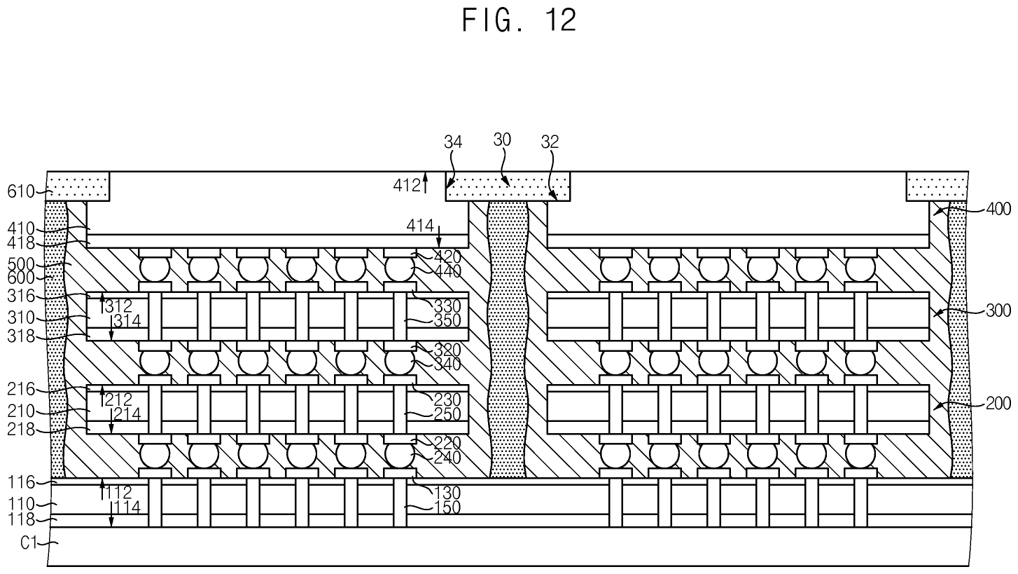

FIG. 11 is a plan view illustrating a semiconductor wafer in which a plurality of semiconductor chips are stacked. FIG. 12 is cross-sectional view taken along the line C-C′ in FIG. 11.

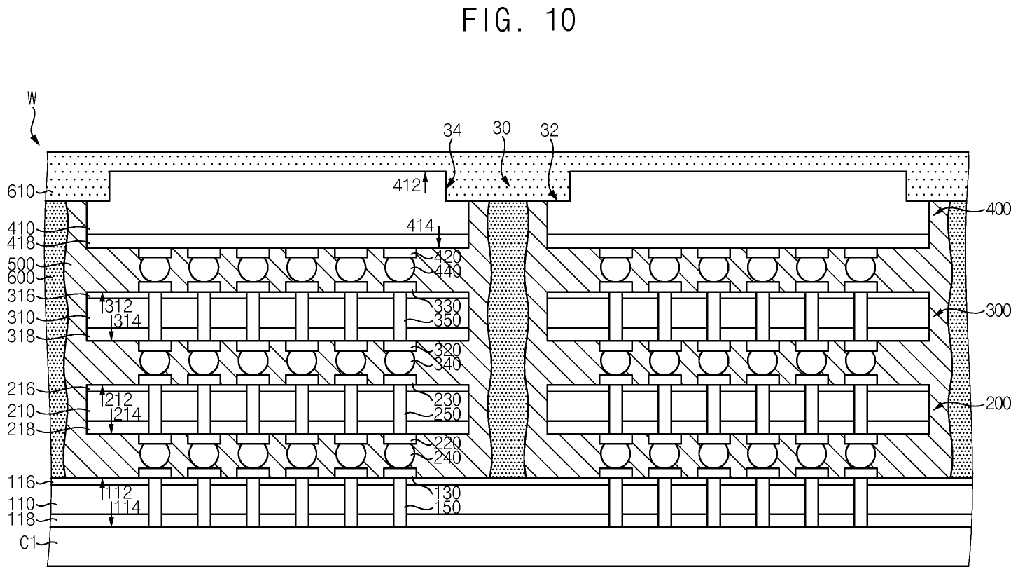

Referring to FIGS. 10 to 12, a second molding member 610 may be formed on the semiconductor wafer W to cover the fourth semiconductor chip 400, the adhesive member 500 and the first molding member 600.

In example embodiments, the second molding member 610 may be formed to cover the upper surface of the fourth semiconductor chip 400 and the trench 30.

The second molding member 610 may be formed by a dispensing process or a spin coating process. The second molding member 610 may include a second mold material different from the first mold material of the first molding member 600. As the first and second mold materials are different, the first and second molding members 600 and 610, respectively, may more strongly fix the first to fourth semiconductor chips 100, 200, 300, and 400. In this regard, the first and second molding materials 600 and 610, respectively, enhance the bonding of the first to fourth semiconductor chips 100, 200, 300, and 400. As the first and second mold materials are different, the first and second molding members 600 and 610 may efficiently discharge heat from a semiconductor package 10.

In one or more examples, the second mold material of the second molding member 610 may include the same material as the first mold material of the first molding member 600. For example, the second mold material may include an epoxy mold compound (EMC), a UV resin, a polyurethane resin, a silicone resin, or a silica filler.

As illustrated in FIGS. 11 and 12, an upper surface of the second molding member 610 may be polished by the substrate support system (WSS). The upper surface of the second molding member 610 may be removed until the upper surface of the fourth semiconductor chip 400 is exposed.

The upper surface of the second molding member 610 may be partially removed by a grinding process such as a chemical mechanical polishing (CMP) process. Thus, a thickness of the second molding member 610 may be reduced to a desired thickness. The upper surface of the fourth semiconductor chip 400 may be exposed from the upper surface of the second molding member 610.

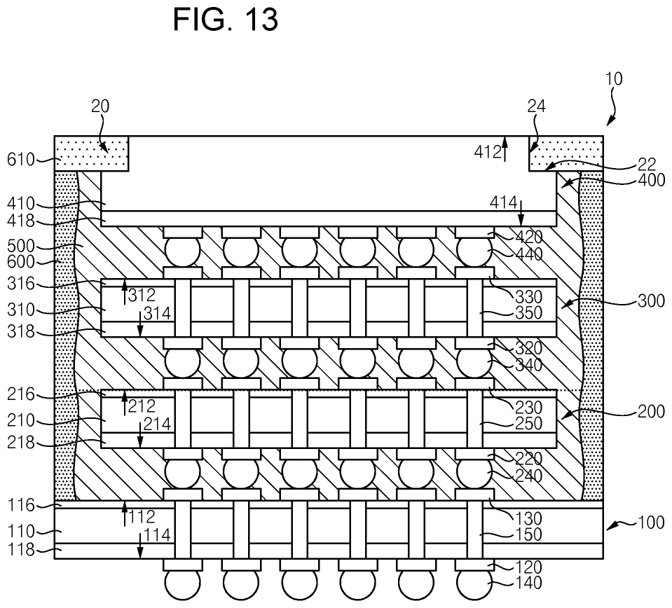

Referring to FIG. 13, the semiconductor wafer W and first and second molding members 600 and 610 may be cut along as the scribe lane region to form the semiconductor package 10 in FIG. 1. The semiconductor wafer W and the first and second molding members 600 and 610 may be cut by a dicing process.

In a process of cutting the semiconductor wafer W and the first and second molding members 600 and 610, the trench 30 may be formed as a stepped portion 20. The bottom surface 32 of the trench 30 may be formed as the horizontal portion 22 of the stepped portion 20.

As described above, in the process of stacking the second to fourth semiconductor chips 200, 300, and 400, respectively, on the first semiconductor chip 100 of the first semiconductor wafer W through the adhesive member 500, the adhesive member 500 may overflow from between the first to fourth semiconductor chips 100, 200, 300, and 400. The edge portions of the fourth semiconductor chip (e.g., uppermost memory die) 400 may be removed along with the overflowed adhesive member 500 to form the stepped portion 20. Since the overflowed adhesive member 500 is removed in a process of forming the stepped portion 20, the adhesive member 500 may not remain on the stepped portion 20. Since the uppermost memory die is once again covered through the second molding member 610, the adhesive member 500 might not be exposed from the second molding member 610.

Since the adhesive member 500 is not exposed from the second molding member 610, a warpage phenomenon of the semiconductor chips that is caused by a difference in coefficients of thermal expansion between the adhesive member 500 and the second molding member 610 may be prevented.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A method of manufacturing a semiconductor package, the method comprising:
stacking, via an adhesive member, a plurality of memory dies to form a memory die stack on a buffer die;
forming a first molding member on the buffer die to cover the memory die stack;
polishing an upper surface of the first molding member to expose an upper surface of an uppermost memory die in the memory die stack, the uppermost memory die positioned in an uppermost layer in the memory die stack;
removing edge portions of the uppermost memory die together with at least a portion of the first molding member and at least a portion of the adhesive member to form a stepped portion; and
forming a second molding member on the first molding member to cover the stepped portion of the uppermost memory die.

2. The method of claim 1, further comprising:
polishing an upper surface of the second molding member to expose the upper surface of the uppermost memory die in the memory stack.

3. The method of claim 1, wherein stacking the plurality of memory dies to form the memory die stack includes allowing the adhesive member to overflow from between the memory dies.

4. The method of claim 3, wherein forming the first molding member to cover the memory die stack further includes covering the at least a portion of the adhesive member that is allowed to overflow from between the plurality of memory dies in the memory die stack with the first molding member.

5. The method of claim 3, wherein removing the edge portions of the uppermost memory die in the memory die stack to form the stepped portion further includes removing the edge portions of the uppermost memory die in the memory die stack together with the portion of the first molding member and the overflowing adhesive member.

6. The method of claim 1, wherein the adhesive member includes a non-conductive film.

7. The method of claim 1, wherein the first molding member includes a first mold material, and
the second molding member includes a second mold material different from the first mold material.

8. The method of claim 7, wherein each of the first and second mold materials includes at least one of an epoxy mold compound (EMC), UV resin, polyurethane resin, silicone resin and silica filler.

9. The method of claim 1, wherein a ratio of (i) a depth of the stepped portion from the upper surface of the uppermost memory die in the memory die stack to (ii) a horizontal portion of the stepped portion is within a range of 10 μm to 100 μm.

10. The method of claim 1, wherein a distance from an outer surface of the uppermost memory die in the memory die stack to a vertical portion of the stepped portion is within a range of 10 μm to 50 μm.

11. A semiconductor package, comprising:
a buffer die;
a plurality of memory dies sequentially stacked to form a memory die stack on the buffer die, the memory die stack including a uppermost memory die that has a stepped portion, the stepped portion extending along edge portions of an upper surface of the uppermost memory die;
an adhesive member filling up between the plurality of memory dies in the memory die stack, the adhesive member overflowing from between the plurality of memory dies under the stepped portion;
a first molding member covering the memory die stack and the adhesive member on the buffer die; and
a second molding member covering the stepped portion of the uppermost memory die in the memory die stack on the first molding member and the adhesive member.

12. The semiconductor package of claim 11, wherein the adhesive member includes a non-conductive film.

13. The semiconductor package of claim 11, wherein each memory die in the memory die stack comprises:
a silicon substrate,
a plurality of chip pads exposed from a lower surface of the silicon substrate, and
a plurality of solder bumps each provided on a respective chip pad from the plurality of chip pads and penetrating the adhesive member.

14. The semiconductor package of claim 13, wherein each memory die in the memory die stack further comprises through electrodes penetrating the silicon substrate in a vertical direction and electrically connected to the chip pads.

15. The semiconductor package of claim 11, wherein the first molding member includes a first mold material, and
the second molding member includes a second mold material different from the first mold material.

16. The semiconductor package of claim 15, wherein each of the first and second mold materials includes at least one of an epoxy mold compound (EMC), UV resin, polyurethane resin, silicone resin and silica filler.

17. The semiconductor package of claim 11, wherein a ratio of (i) a depth from the upper surface of the uppermost memory die in the memory die stack to (ii) a horizontal portion of the stepped portion is within a range of 10 μm to 100 μm.

18. The semiconductor package of claim 11, wherein a distance from an outer surface of the uppermost memory die in the memory die stack to a vertical portion of the stepped portion is within a range of 10 μm to 50 μm.

19. The semiconductor package of claim 11, wherein a ratio (A2/A1) of an area A1 of the upper surface and an area A2 of a lower surface of the uppermost memory die in the memory die stack is within a range of 1.01 to 1.1.

20. A method of manufacturing a semiconductor package, the method comprising:
stacking a plurality of memory dies to form a memory die stack on a buffer die via an adhesive member;
forming a first molding member on the buffer die to cover the memory die stack and a portion of the adhesive member that overflows from between the memory dies;
polishing an upper surface of the first molding member to expose an upper surface of an uppermost memory die in the memory die stack, the uppermost memory die positioned in an uppermost layer in the memory die stack;
removing edge portions of the uppermost memory die in the memory die stack together with at least a portion of the first molding member and at the portion of the adhesive member to form a stepped portion;
forming a second molding member on the first molding member to cover the stepped portion of the uppermost memory die in the memory die stack; and
polishing an upper surface of the second molding member to expose the upper surface of the uppermost memory die in the memory die stack.
